(19) United States
(12) Patent Application Publication
(10) Pub. No.: US 2014/0361325 A1
(43) Pub. Date: Dec. 11, 2014

(54) PACKAGE STRUCTURE AND METHOD FOR MANUFACTURING THE SAME

(71) Applicant: LEXTAR ELECTRONICS CORPORATION, HSINCHU (TW)

(72) Inventors: Tsung-Han LI, New Taipei City (TW); Lei-Hsing LIU, Hsinchu City (TW); Chih-Tsang WEI, New Taipei City (TW)

(73) Assignee: LEXTAR ELECTRONICS CORPORATION, HSINCHU (TW)

(21) Appl. No.: 14/279,252

(22) Filed: May 15, 2014

(30) Foreign Application Priority Data
Jun. 5, 2013 (TW) 102119884

(51) Int. Cl. H01L 33/50; H01L 33/62; H01L 33/56

(52) U.S. Cl. CPC H01L 33/507; H01L 33/56; H01L 33/62
USPC 257/98; 438/27

(57) ABSTRACT

A package structure and methods for forming the package structure are provided. The package structure includes a lead frame having a chip bonding area and a shell surrounding a portion of the lead frame. The shell has an inner surface and an outer surface opposite to the inner surface. A cavity is recessed from the inner surface, and the chip bonding area is exposed from the cavity. The structure further includes a light emitting diode chip disposed over the chip bonding area and a first glue layer disposed in the cavity to cover the light emitting diode chip. A separation film is disposed on the first glue layer in the cavity and a second glue layer disposed on the separation film in the cavity. The second glue layer contains a wavelength conversion material and the first glue layer does not contain any wavelength conversion material.

### CROSS REFERENCE TO RELATED APPLICATIONS

This Application claims priority of Taiwan Patent Application No. 102119884, filed on Jun. 5, 2013, the entirety of which is incorporated by reference herein.

### BACKGROUND OF THE DISCLOSURE

1. Field of the Invention

The present invention relates to a package structure and a method for forming the same, and in particular it relates to a package structure having a separation film and a method for forming the same.

2. Description of the Related Art

Light emitting diodes (LED) have a small size, low electrical consumption, long life-time, and short response-time, and therefore they have been broadly used in various products in recent years.

An LED is a semiconductor element that can convert electricity into light. However, one LED can only emit light of a specific wavelength. Therefore, a wavelength conversion material is required to convert the wavelength of the light emitted by the LED into a chosen wavelength. The wavelength conversion material may be phosphor powder. The phosphor powder is dispersed in encapsulant, and the encapsulant is applied on an LED chip by a dispensing process. However, since the phosphor powder and the encapsulant are immiscible, the distribution of the phosphor powder may be uneven. In addition, the phosphor powder is expensive, and thus the cost of forming the LED may be reduced if less phosphor powder is used during the formation of the LED.

### BRIEF SUMMARY OF THE DISCLOSURE

A detailed description is given in the following embodiments with reference to the accompanying drawings.

In some embodiments, a package structure includes a lead frame having a chip bonding area is provided. The package structure includes a shell surrounding a portion of the lead frame, and the shell has an inner surface and an outer surface opposite to the inner surface. A cavity is recessed from the inner surface, and the chip bonding area is exposed from the cavity. The package structure further includes a light emitting diode chip disposed over the chip bonding area and a first glue layer disposed in the cavity to cover the light emitting diode chip. The package structure further includes a separation film disposed on the first glue layer in the cavity and a second glue layer disposed on the separation film in the cavity. In addition, the second glue layer contains a wavelength conversion material and the first glue layer does not contain any wavelength conversion material.

In some embodiments, a method for forming a package structure is provided. The method includes providing a package unit. The package unit includes a lead frame having a chip bonding area and a shell surrounding a portion of the lead frame. The shell has an inner surface and an outer surface opposite to the inner surface, and a cavity is recessed from the inner surface. The chip bonding area is exposed from a bottom of the cavity. The package unit further includes a light emitting diode chip disposed over the chip bonding area. The method for forming a package structure further includes forming a first glue layer covering the light emitting diode chip and disposing a separation film on the first glue layer. The method further includes forming a second glue layer on the separation film in the cavity, and the second glue layer contains a wavelength conversion material and the first glue layer does not contain any wavelength conversion material.

In some embodiments, a method for forming a package structure is provided. The method includes providing a package unit. The package unit includes a lead frame having a chip bonding area and a shell surrounding a portion of the lead frame. The shell has an inner surface and an outer surface opposite to the inner surface, and a cavity is recessed from the inner surface. The chip bonding area is exposed from a bottom of the cavity. The package unit further includes a light emitting diode chip disposed over the chip bonding area. The method for forming a package structure further includes disposing a separation film on the light emitting diode chip, and the separation film has a plurality of pores and an edge of the separation film is in contact with an inner surface of the cavity. The method further includes providing a encapsulant having a wavelength conversion material mixed therein, and a pore size of the pore of the separation film is smaller than a particle size of the wavelength conversion material. The method further includes filling the encapsulant into the cavity, such that the encapsulant passes through the separation film to form a first glue layer without containing the wavelength conversion material, while the encapsulant over the separation film forms a second glue layer containing the wavelength conversion material.

### BRIEF DESCRIPTION OF THE DRAWINGS

The present invention can be more fully understood by reading the subsequent detailed description and examples with references made to the accompanying drawings, wherein:

FIG. 1 is a cross-sectional representation of a package structure in accordance with one embodiment of the disclosure.

FIG. 2 is a flow chart of a method for forming a package structure in accordance with some embodiments.

FIGS. 3A to 3D are cross-sectional representations of various stages of forming a package structure according to the method shown in FIG. 2 in accordance with some embodiments.

FIG. 4 is a cross-sectional representation of a package structure in accordance with a second embodiment of the disclosure.

FIG. 5 is a flow chart of forming a package structure in accordance with a second embodiment.

FIGS. 6A to 6E are cross-sectional representations of various stages of forming a package structure according to the method shown in FIG. 5 in accordance with some embodiments.

### DETAILED DESCRIPTION OF THE DISCLOSURE

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

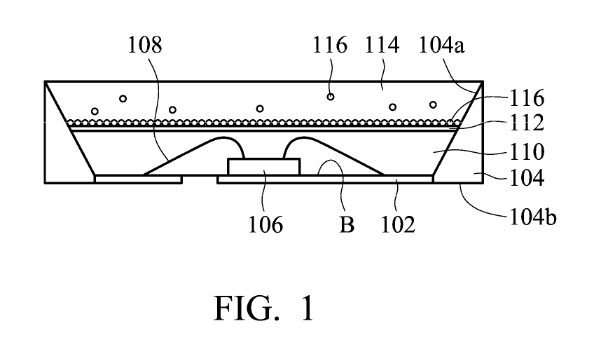

FIG. 1 is a cross-sectional representation of a package structure in accordance with one embodiment of the disclosure. The package structure includes a lead frame 102 having a chip bonding area B and a shell 104 surrounding a portion of the lead frame 102. The shell 104 has an inner surface 104a and an outer surface 104b opposite to the inner surface 104a. A cavity is recessed from the inner surface 104a, and the chip bonding area B is exposed from the cavity. The package structure further includes a light emitting diode chip 106 disposed over the chip bonding area B and a first glue layer 110 disposed in the cavity to cover the light emitting diode chip 106. The package structure further includes a separation film 112 disposed on the first glue layer 110 in the cavity and a second glue layer 114 formed on the separation film 112 in the cavity. In addition, the second glue layer 114 contains a wavelength conversion material 116 and the first glue layer 114 does not contain any wavelength conversion material.

In addition, as shown in FIG. 1, the package structure may further include a wire 108, which electrically connects the light emitting diode chip 106 and the lead frame 102. It should be noted that the light emitting diode chip may be attached to the lead frame by flip chip without using the wire 108 in accordance with some other embodiments.

The separation film 112 may be an organic polymer film. For example, the separation film 112 may be made of nylon filament, polypropylene, polytetrafluoroethene, cellulose ester, or a combination thereof. The separation film 112 may have a thickness in a range from about 1 μm to about 50 μm. The thickness of the separation film 112 should not be too thick, or the performance of the package structure may be affected. One skilled in the art may adjust the thickness of the separation film according to its application, and the scope of the disclosure is not intended to be limiting.

The first glue layer 110 may include any known encapsulant material or any encapsulant material developed in the future, such as silicone gel or epoxy resin. In addition, the first glue layer 110 does not include any wavelength conversion material. The first glue layer 110 may have a thickness in a range from about 0.1 mm to about 0.4 mm. One skilled in the art may adjust the thickness of the first glue layer 110 according to its application, and the scope of the disclosure is not intended to be limiting.

The second glue layer 114 may include any known encapsulant material or any encapsulant material developed in the future, such as silicone gel or epoxy resin. In addition, the wavelength conversion material 116 is dispersed in the second glue layer 114. In some embodiments, the wavelength conversion material 116 is phosphor powder, pigment, dye, or a combination thereof. In one embodiment, the first glue layer 110 and the second glue layer 114 are made of the same encapsulant, such that they can have a better compatibility. The second glue layer 114 may have a thickness in a range from about 0.1 mm to about 0.4 mm. In one embodiment, the thickness of the second glue layer 114 is smaller than the thickness of the first glue layer 110. However, one skilled in the art may adjust the thickness and the material of the second glue layer 114 according to its application, and the scope of the disclosure is not intended to be limiting.

It should be noted that the second glue layer 114 contains the wavelength conversion material 116, while the first glue layer 110 does not contain any wavelength conversion material. In addition, the wavelength conversion material 116 in the second glue layer 114 is dispersed (located) on the top surface of the separation film 112 and/or at the bottom portion of the second glue layer 114 near the separation film 112. As shown in FIG. 1, most of the wavelength conversion material 116 is dispersed at the interface between the second glue layer 114 and the separation film 112. In addition, the wavelength conversion material 116 may be settled in the second glue layer 114 by natural sedimentation or centrifugation deposition methods. However, it should be noted that some wavelength conversion material 116 does not reach the separation film 112 and therefore is still suspended in the second glue layer 114, as shown in FIG. 1.

In a conventional package structure, the cavity in the package structure is filled with the encapsulant containing a wavelength conversion material mixed therein, such as phosphor powder. Therefore, the wavelength conversion material is dispersed in a relatively large region and it is difficult to evenly disperse the wavelength conversion material in the encapsulant. As a result, a greater amount of wavelength conversion material is required. In addition, even if the wavelength conversion material may also be settled by natural sedimentation or centrifugation deposition methods, it may still fail to convert the wavelength of the light emitted by the LED chip effectively due to the distribution of the wavelength conversion material being uneven or due to the amount of the wavelength conversion material being insufficient.

On the other hand, in some embodiments of the disclosure, the separation film is used to divide the first glue layer and the second glue layer, and the wavelength conversion material is only dispersed in the second glue layer. Therefore, the wavelength conversion material is dispersed in a relatively smaller region and the separation film enables the wavelength conversion material to be dispersed on the separation film more evenly. As a result, less wavelength conversion material is required, and the cost of forming the package structure is reduced. In addition, the wavelength conversion material in the second glue layer is separated from the heating source, such as the lead frame and LED chip, for a relatively longer distance, and therefore its reliability is improved.

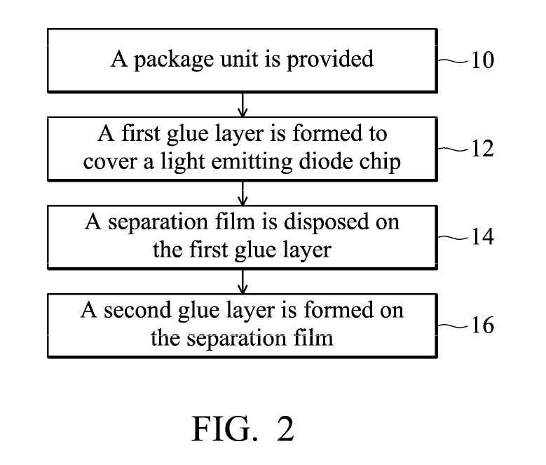

FIG. 2 is a flow chart of a method for forming a package structure in accordance with some embodiments. In step 10, a package unit is provided. In step 12, a first glue layer is formed to cover a light emitting diode chip. In step 14, a separation film is disposed on the first glue layer. In step 16, a second glue layer is formed on the separation film.

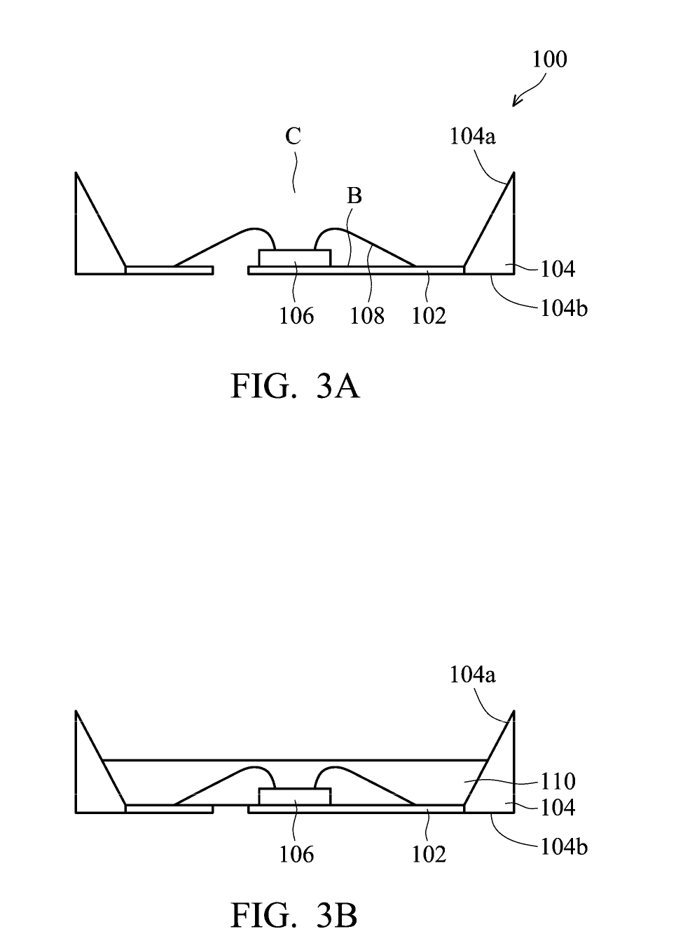

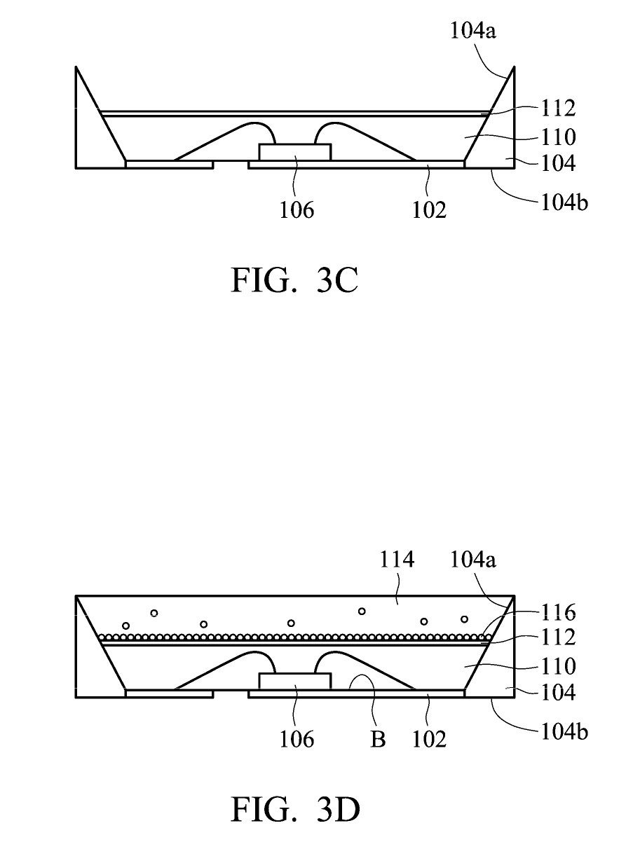

FIGS. 3A to 3D are cross-sectional representations of various stages of forming a package structure according to the method shown in FIG. 2 in accordance with some embodiments. The package structure shown in FIGS. 3A to 3D may be similar to the package structure shown in FIG. 1, and therefore the details of some structures and materials are not repeated herein. Referring to FIGS. 2 and FIG. 3 (e.g. FIGS. 3A to 3B), a package unit 100 is provided in step 10. The package unit 100 includes the lead frame 102 having the chip bonding area B, a shell 104 surrounding a portion of the lead frame 102, and the light emitting diode chip 106 disposed over the chip bonding area B. The shell 104 has an inner surface 104a and an outer surface 104b opposite to the inner surface 104a, and a cavity C is recessed from the inner surface 104a. The chip bonding area B is exposed from a bottom of the cavity C. In some embodiments, the cavity C has a thickness in a range from about 0.1 mm to about 0.6 mm. It should be noted that the size of the cavity C may be adjusted according to its application, and the scope of the disclosure is not intended to be limiting. In addition, as shown in FIG. 3A, the package unit 100 may further include the wire 108 for electrically connecting the LED chip 106 and lead frame 102.

Referring to FIG. 2 and FIG. 3 (e.g. FIGS. 3A to 3D), the first glue layer 110 is formed to cover the light emitting diode chip 106 in step 12. In some embodiments, the first glue layer 110 is formed by a dispensing process. However, the first glue layer may be formed by other coating processes or any applicable processes in accordance with some other embodiments. The first glue layer 110 may include any known encapsulant material or any encapsulant material developed in the future, such as silicone gel or epoxy resin. In addition, the first glue layer 110 does not contain any wavelength conversion material.

Referring to FIG. 2 and FIG. 3 (e.g. FIGS. 3A to 3D), the separation film 112 is disposed on the first glue layer 110 in step 14. As shown in FIG. 3C, the separation film 112 may be disposed directly on the first glue layer 110, such that the separation film 112 is in direct contact with the top surface of the first glue layer 110. The separation film 112 may be formed by a wet-type film forming method, a dry-type film forming method, or other applicable methods. In some embodiments, the separation film 112 is an organic polymer film. In some embodiments, the separation film 112 is made of nylon filament, polypropylene, polytetrafluoroethene, cellulose ester, or a combination thereof. The separation film 112 may have a thickness in a range from about 1 μm to about 50 μm. The thickness of the separation film 112 should not be too thick, or the performance of the package structure may be affected in accordance with some embodiments. One skilled in the art may adjust the thickness of the separation film according to its application, and the scope of the disclosure is not intended to be limiting.

Referring to FIG. 2 and FIG. 3 (e.g. FIGS. 3A to 3D), the second glue layer 114 is formed on the separation film 112 in step 16. In some embodiments, the second glue layer 114 is formed by a dispensing process. However, the second glue layer 114 may be formed by other coating processes or any applicable processes in accordance with some other embodiments. The second glue layer 114 may include any known encapsulant material or any encapsulant material developed in the future, such as silicone gel or epoxy resin. In addition, the wavelength conversion material 116 is mixed in the second glue layer 110. The wavelength conversion material 116 is phosphor powder, pigment, dye, or a combination thereof in accordance with some embodiments. In some embodiments, the wavelength conversion material 116 is settled by natural sedimentation or centrifugation deposition methods, such that the wavelength conversion material 116 is located on the top surface of the separation film 112 and/or at the bottom portion of the second glue layer 114 near the separation film 112.

As shown in FIG. 3D, most of the wavelength conversion material 116 is dispersed on the top surface of the separation film 112 and the bottom portion of the second glue layer 114. However, some wavelength conversion material 116 may still be suspended in the second glue layer 114. Compared to the package structure having the wavelength conversion material dispersed in the whole encapsulant layer, the wavelength conversion material 116 is dispersed in a relatively smaller region. Therefore, the wavelength conversion material 116 can be distributed on the separation film 112 more evenly, and the amount of the wavelength conversion material 116 used in the package structure is reduced.

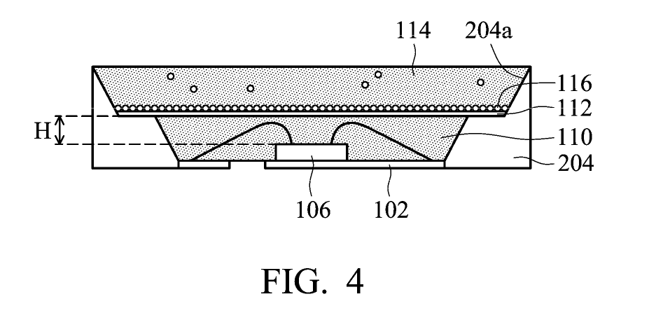

FIG. 4 is a cross-sectional representation of a package structure in accordance with a second embodiment of the disclosure. In the present embodiment, the structures and the materials of the lead frame 102, the LED chip 106, the first glue layer 110, the second glue layer 114, and the wavelength conversion material 116 may be similar to, or the same as, those of the package structure shown in FIG. 1. However, in the present embodiment, the separation film 112 further includes a plurality of pores. In addition, the pore size of the pore of the separation film 112 is smaller than the particle size of the wavelength conversion material 116. For example, the diameter of the pore in the separation film 112 is in a range from about 1 μm to about 5 μm. In addition, the cavity in a shell 204 of the package structure has a stepwise structure, and the top surface of the stepwise structure is higher than the top surface of the light emitting diode chip 106. As shown in FIG. 4, the separation film 112 may be disposed on the top surface of the stepwise structure, and the separation film 112 and the top surface of the LED chip 106 is separated by a distance H. The stepwise structure enables the separation film 112 to be firmly fixed on the first glue layer 110.

As described previously, since the separation film 112 is also applied in the package structure shown in FIG. 4, the wavelength conversion material 116 is also substantially distributed in a region near the separation film. Therefore, the amount of the wavelength conversion material 116 used in the package structure shown in FIG. 4 is reduced, and the cost of forming the package structure is also reduced. Furthermore, the wavelength conversion material 116 in the second glue layer 114 is separated from the heating source, such as lead frame 204 and LED chip 106, for a relatively longer distance, and therefore its color rendering index is improved.

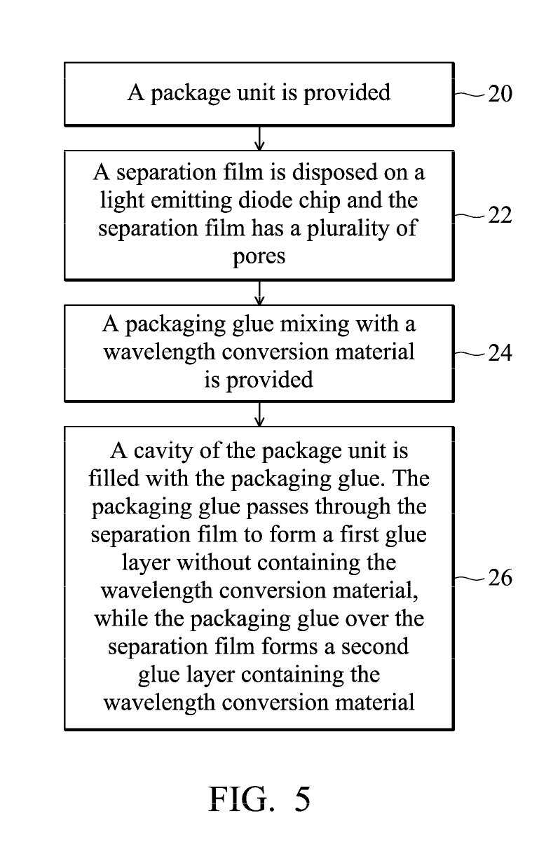

FIG. 5 is a flow chart of forming a package structure in accordance with a second embodiment. In step 20, a package unit is provided. In step 22, a separation film is disposed on a light emitting diode chip and the separation film has a plurality of pores. In step 24, a encapsulant mixing with a wavelength conversion material is provided. In step 26, a cavity of the package unit is filled with the encapsulant. The encapsulant passes through the separation film to form a first glue layer without containing the wavelength conversion material, while the encapsulant over the separation film forms a second glue layer containing the wavelength conversion material.

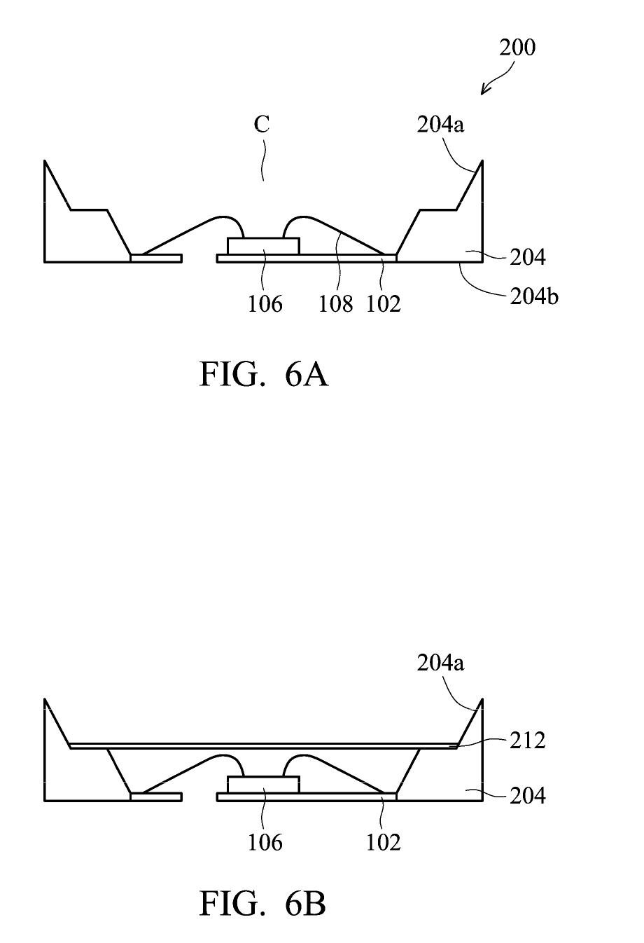

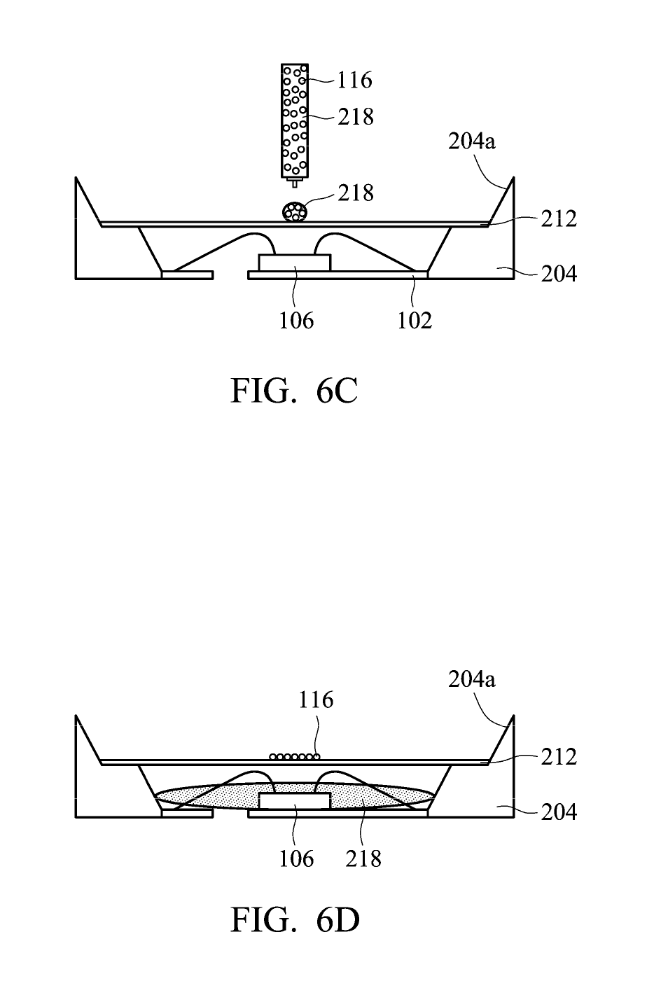

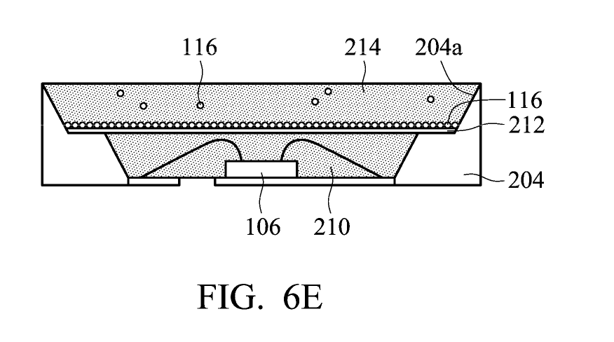

FIGS. 6A to 6E are cross-sectional representations of various stages of forming a package structure according to the method shown in FIG. 5 in accordance with some embodiments. Referring to FIG. 5 and FIG. 6 (e.g. FIGS. 6A to 6E), a package unit 200 is provided in step 20. The package unit 200 includes a lead frame 102 having a chip bonding area B, a shell 204 surrounding a portion of the lead frame 102, and a light emitting diode chip 106 disposed over the chip bonding area B. The shell 204 has an inner surface 204a and an outer surface 204b opposite to the inner surface 204a, and a cavity C is recessed from the inner surface 204a, and the chip bonding area B is exposed from a bottom of the cavity C. As shown in FIG. 6A, the inner surface 204a of cavity C has a stepwise structure, and the top surface of the stepwise structure is higher than the top surface of the LED chip 106.

Referring to FIG. 5 and FIG. 6 (e.g. FIGS. 6A to 6E), the separation film 202 is disposed over the light emitting diode chip 106 and the separation film 202 has a plurality of pores in step 22. As shown in FIG. 6B, the separation film 212 is disposed on the top surface of the horizontal portion of the stepwise structure, and the edges of the separation film 212 are in contact with the inner surface 204a of the cavity C. In addition, the separation film 212 is separated from the lead frame 102 by a distance, such that the separation film 212 is not in direct contact with the lead frame 102. In some embodiments, the distance between the separation film 212 and the lead frame 102 is in a range from about 0.1 mm to about 0.4 mm.

In the second embodiment, the separation film 212 includes a number of pores. The diameter of the pore is in a range from about 1 μm to about 5 μm in accordance with some embodiments. In one embodiment, the separation film 212 is formed by a dry-type film forming method. For example, the material used to form the separation film is melted and pressed to form a thin layer. Next, an annealing process is performed. After the annealing process, the thin film is pulled to form pores in the film, and the film is stretched further at a high temperature to form the separation film 212 having a number of pores therein. In another embodiment, the separation film 212 is formed by a wet-type film forming method. For example, the material used to form the separation film is mixed with a diluent. The mixture is used to form a thin film at a high temperature, and a cooling process is performed afterwards. Next, the diluent is extracted from the thin film to form pores in the film. Accordingly, a separation film having pores formed therein is formed. In one embodiment, the separation film 212 is an organic polymer film. In some embodiments, the separation film 212 is made of nylon filament, polypropylene, polytetrafluoroethene, cellulose ester, or a combination thereof.

Referring to FIG. 5 and FIG. 6 (e.g. FIGS. 6A to 6E), a encapsulant 218 containing the wavelength conversion material 116 mixed therein is provided in step 24. In the present embodiment, the particle size of the wavelength conversion material 116 is larger than the pore size of the separation film 212. The wavelength conversion material 116 may be inorganic powders, such as phosphor powder, pigment, dye, or a combination thereof. The diameter of the particle of the wavelength conversion material 116 is in a range from about 6 μm to about 20 μm in accordance with some embodiments. In step 24, the wavelength conversion material 116 is directly added into the package glue 218 and is mixed with the package glue 218 evenly. Therefore, the wavelength conversion material 116 is evenly dispersed in the package glue 218.

Referring to FIG. 5 and FIG. 6 (e.g. FIGS. 6A to 6E), the cavity C of the package unit 200 is filled with the encapsulant 218 containing the wavelength conversion material 116 in step 26. As shown in FIG. 6D, since the particle size of the wavelength conversion material 116 is larger than the pore size of the separation film 212, the wavelength conversion material 116 is left on the top surface of the separation film 212. Therefore, the encapsulant 218 passes through the separation film 212 to cover the LED chip 106 without containing the wavelength conversion material 116. In one embodiment, the separation film 212 is an organic polymer film, and the wavelength conversion material 116 is an inorganic material, such as phosphor powder. In the embodiment, since the separation film 212 is made of organic material and the wavelength conversion material 116 is an inorganic material and the particle size of the wavelength conversion material 116 is larger than the pore size of the separation film 212, the encapsulant 218 can pass through the separation film 212 while the wavelength conversion material 116 cannot pass through the separation film 212. Therefore, a layer of wavelength conversion material 116 (e.g. a phosphor powder layer) is formed on the separation film 212, such that the wavelength conversion material 116 is evenly dispersed on the separation film 212. As a result, the amount of the wavelength conversion material 116 used in the package structure can be reduced.

Referring to FIG. 5 and FIG. 6 (FIGS. 6A to 6E), the process of step 26 is repeated, such that a region between the lead frame 102 and the separation film 212 (i.e. a bottom portion of the cavity C) is completely filled by the encapsulant 218 (without containing any wavelength conversion material) to form a first glue layer 210. In addition, the encapsulant 218 which does not pass through the separation film 212 forms a second glue layer 214 containing the wavelength conversion material 116 over the separation film 212. In one embodiment, the wavelength conversion material 116 is settled by natural sedimentation or centrifugation deposition methods, such that the wavelength conversion material 116 is located at the bottom portion of the second glue layer 214 near the separation film 212. As shown in FIG. 6E, most of the wavelength conversion material 116 is dispersed at the interface between the second glue layer 214 and the separation film 212. However, some wavelength conversion material 116 may still be suspended in the second glue layer 214.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A package structure, comprising
a lead frame having a chip bonding area;
a shell surrounding a portion of the lead frame, wherein the shell has an inner surface and an outer surface opposite to the inner surface, and a cavity is recessed from the inner surface, and the chip bonding area is exposed from the cavity;
a light emitting diode chip disposed over the chip bonding area;
a first glue layer disposed in the cavity to cover the light emitting diode chip;
a separation film disposed on the first glue layer in the cavity; and
a second glue layer disposed on the separation film in the cavity,
wherein the second glue layer contains a wavelength conversion material and the first glue layer does not contain any wavelength conversion material.

2. The package structure as claimed in claim 1, wherein the separation film is an organic polymer film.

3. The package structure as claimed in claim 2, wherein the separation film is made of nylon filament, polypropylene, polytetrafluoroethene, cellulose ester, or a combination thereof.

4. The package structure as claimed in claim 1, wherein the wavelength conversion material is located on a top surface of the separation film and/or at a bottom portion of the second glue layer near the separation film.

5. The package structure as claimed in claim 1, wherein cavity has a stepwise structure, such that the separation film is disposed on a top surface of the stepwise structure, and the top surface of the stepwise structure is higher than a top surface of the light emitting diode chip.

6. The package structure as claimed in claim 1, wherein a thickness of the second glue layer is smaller than a thickness of the first glue layer.

7. The package structure as claimed in claim 1, wherein the wavelength conversion material is phosphor powder, pigment, dye, or a combination thereof.

8. The package structure as claimed in claim 1, wherein the separation film comprises a plurality of pores, and a pore size of the pore of the separation film is smaller than a particle size of the wavelength conversion material.

9. A method for forming a package structure, comprising
providing a package unit, wherein the package unit comprises:
a lead frame having a chip bonding area;
a shell surrounding a portion of the lead frame, wherein the shell has an inner surface and an outer surface opposite to the inner surface, and a cavity is recessed from the inner surface, and the chip bonding area is exposed from a bottom of the cavity; and
a light emitting diode chip disposed over the chip bonding area;
forming a first glue layer covering the light emitting diode chip;
disposing a separation film on the first glue layer; and
forming a second glue layer on the separation film in the cavity,
wherein the second glue layer contains a wavelength conversion material and the first glue layer does not contain any wavelength conversion material.

10. The method for forming a package structure as claimed in claim 9, wherein the separation film is an organic polymer film.

11. The method for forming a package structure as claimed in claim 9, wherein the separation film is made of nylon filament, polypropylene, polytetrafluoroethene, cellulose ester, or a combination thereof.

12. The method for forming a package structure as claimed in claim 9, wherein the wavelength conversion material is settled by natural sedimentation or centrifugation deposition methods, such that the wavelength conversion material is positioned on a top surface of the separation film and/or at a bottom portion of the second glue layer near the separation film.

13. The method for forming a package structure as claimed in claim 9, wherein the cavity has a stepwise structure, such that the separation film is disposed on a top surface of the stepwise structure, and the top surface of the stepwise structure is higher than a top surface of the light emitting diode chip.

14. The method for forming a package structure as claimed in claim 9, wherein the wavelength conversion material is phosphor powder, pigment, dye, or a combination thereof.

15. A method for forming a package structure, comprising
providing a package unit, wherein the package unit comprises:
a lead frame having a chip bonding area;
a shell surrounding a portion of the lead frame, wherein the shell has an inner surface and an outer surface opposite to the inner surface, and a cavity is recessed from the inner surface, and the chip bonding area is exposed from a bottom of the cavity; and
a light emitting diode chip disposed over the chip bonding area;
disposing a separation film on the light emitting diode chip, wherein the separation film has a plurality of pores and an edge of the separation film is in contact with an inner surface of the cavity;
providing a encapsulant having a wavelength conversion material mixed therein, wherein a pore size of the pore of the separation film is smaller than a particle size of the wavelength conversion material; and
filling the encapsulant into the cavity, such that the encapsulant passes through the separation film to form a first glue layer without containing the wavelength conversion material, while the encapsulant over the separation film forms a second glue layer containing the wavelength conversion material.

16. The method for forming a package structure as claimed in claim 15, wherein the separation film is an organic polymer film.

17. The method for forming a package structure as claimed in claim 16, wherein the separation film is made of nylon filament, polypropylene, polytetrafluoroethene, cellulose ester, or a combination thereof.

18. The method for forming a package structure as claimed in claim 15, wherein the wavelength conversion material is settled by natural sedimentation or centrifugation deposition methods, such that the wavelength conversion material is positioned on a top surface of the separation film and/or at a bottom portion of the second glue layer near the separation film.

19. The method for forming a package structure as claimed in claim 15, wherein the cavity has a stepwise structure, such that the separation film is disposed on a top surface of the stepwise structure, and the top surface of the stepwise structure is higher than a top surface of the light emitting diode chip.

20. The method for forming a package structure as claimed in claim 15, wherein the wavelength conversion material is phosphor powder, pigment, dye, or a combination thereof.
